(19) United States
(12) Patent Application Publication
(10) Pub. No.: US 2011/0115503 A1
(43) Pub. Date: May 19, 2011

(54) Capacitance Measurement Circuit and Method Therefor

(75) Inventors: Shih-Tzung Chou, Zhudong Township (TW); Yong-Nien Rao, Hsinchu City (TW); Yu Kuang, Hsinchu City (TW)

(73) Assignee: Raydium Semiconductor Corporation, Hsinchu (TW)

(21) Appl. No.: 12/947,089

(22) Filed: Nov. 16, 2010

(30) Foreign Application Priority Data
Nov. 19, 2009 (TW) 98139380

(51) Int. Cl. G01R 27/26

(52) U.S. Cl. 324/679

(57) ABSTRACT

A capacitance measurement circuit includes: a reference capacitor selectively coupled to a first reference voltage or a second reference voltage; a sensor capacitor selectively coupled to the first reference voltage or the second reference voltage; an operation amplifier coupled to the reference capacitor, the sensor capacitor and a third reference voltage; an approximation unit coupled to the operation amplifier; and a conversion unit coupled to the operation amplifier and the approximation unit. The reference capacitor and the sensor capacitor respectively couple a first charge amount and a second charge amount to a first input terminal of the operational amplifier to conduct an input voltage. The conversion unit couples a third charge amount to the first input terminal of the operation amplifier or charges/discharges the first input terminal of the operation amplifier until the input voltage approximates the third reference voltage.

This application claims the benefit of Taiwan application Serial No. 98139380, filed Nov. 19, 2009, the subject matter of which is incorporated therein by reference.

### TECHNICAL FIELD

The disclosure relates in general to a capacitance measurement circuit and a method thereof, and more particularly to a capacitance measurement circuit which uses conversion unit and operates without coupling capacitor and a method thereof.

### BACKGROUND

Conventionally, the user control interface is normally implemented by a mechanical switch. The conventional mechanical device may be damaged easily. Currently, touch switch such as capacitive switch is already provided.

To further improve the convenience of use, the touch panel or the display touch panel (with both the display function and the touch control function) capable of receiving user's input and clicking is provided. The touch panel or the display touch panel can be used in various electronic devices such as mobile phone. Thus, the user can operate an electronic device by touching images displayed on the touch panel or the display touch panel, so that the operation is made more convenient and friendly. The touch panel or the display touch panel has many varieties such as capacitive touch panel and capacitive display touch panel.

When the user operates the capacitive touch panel, the capacitive display touch panel, or the capacitive switch, the capacitance of the sensor capacitor therein varies with the user's operation. Therefore, if the capacitance of the sensor capacitor and its change can be detected, the user's operation will be detected (sensed). Thus, how to provide a capacitance measurement circuit, capable of effectively detecting the capacitance of the sensor capacitor and its change so as to improve the function of the capacitive touch panel, the capacitive display touch panel, or the capacitive switch, has become a prominent task for the industries.

However, the conventional capacitance measurement circuit requires coupling capacitors in addition to a conversion unit, making it difficult to decrease the circuit area or reduce the circuit cost.

### BRIEF SUMMARY

The disclosure is directed to a capacitance measurement circuit and a method thereof. Since the capacitance measurement circuit can measure without additional coupling capacitors, the circuit area is decreased and the circuit cost reduced.

According to a first example of the present disclosure, a capacitance measurement circuit includes: a reference capacitor having a first terminal and a second terminal, the first terminal selectively connected to a first reference voltage or a second reference voltage; a sensor capacitor having a first terminal and a second terminal, the first terminal selectively connected to the first reference voltage or the second reference voltage; an operation amplifier having a first input terminal, a second input terminal and an output terminal, the first input terminal connected to the second terminal of the reference capacitor and the second terminal of the sensor capacitor, and the second input terminal connected to a third reference voltage; an approximation unit having an input terminal and an output terminal, the input terminal connected to the output terminal of the operation amplifier; and a conversion unit having an input terminal and an output terminal, the input terminal connected to the output terminal of the approximation unit, and the output terminal is directly connected to the first input terminal of the operation amplifier. The reference capacitor and the sensor capacitor respectively couple a first charge amount and a second charge amount to the first input terminal of the operational amplifier to conduct an input voltage at the first input terminal of the operational amplifier. The conversion unit directly couples a third charge amount to the first input terminal of the operation amplifier or the conversion unit charges or discharges the first input terminal of the operation amplifier, until the input voltage at the first input terminal of the operation amplifier approximates the third reference voltage.

According to a second example of the present disclosure, a capacitance measurement method includes: initializing an operation amplifier; selectively switching a reference capacitor to a first reference voltage or a second reference voltage to couple a first charge amount to a first input terminal of the operation amplifier, wherein a second input terminal of the operation amplifier is connected to a third reference voltage; selectively switching a sensor capacitor to the first reference voltage or the second reference voltage to couple a second charge amount to the first input terminal of the operation amplifier; comparing an input voltage at the first input terminal of the operation amplifier with the third reference voltage; and directly coupling a third charge amount to the first input terminal of the operation amplifier or charging/discharging the first input terminal of the operation amplifier according to the comparison result by successive approximation until the input voltage approximates the third reference voltage, wherein a successive approximation result reflects a capacitance of the sensor capacitor.

It is to be understood that both the foregoing general description and the following detailed description are exemplary and explanatory only and are not restrictive of the disclosed embodiments, as claimed.

### BRIEF DESCRIPTION OF THE DRAWINGS

FIG. 1 shows a capacitance measurement circuit according to a first embodiment of the disclosure;

FIG. 2 shows a capacitance measurement circuit according to a second embodiment of the disclosure;

FIG. 3 shows a capacitance measurement circuit according to a third embodiment of the disclosure; and

FIG. 4 shows a capacitance measurement circuit according to a fourth embodiment of the disclosure.

### DETAILED DESCRIPTION OF THE DISCLOSURE

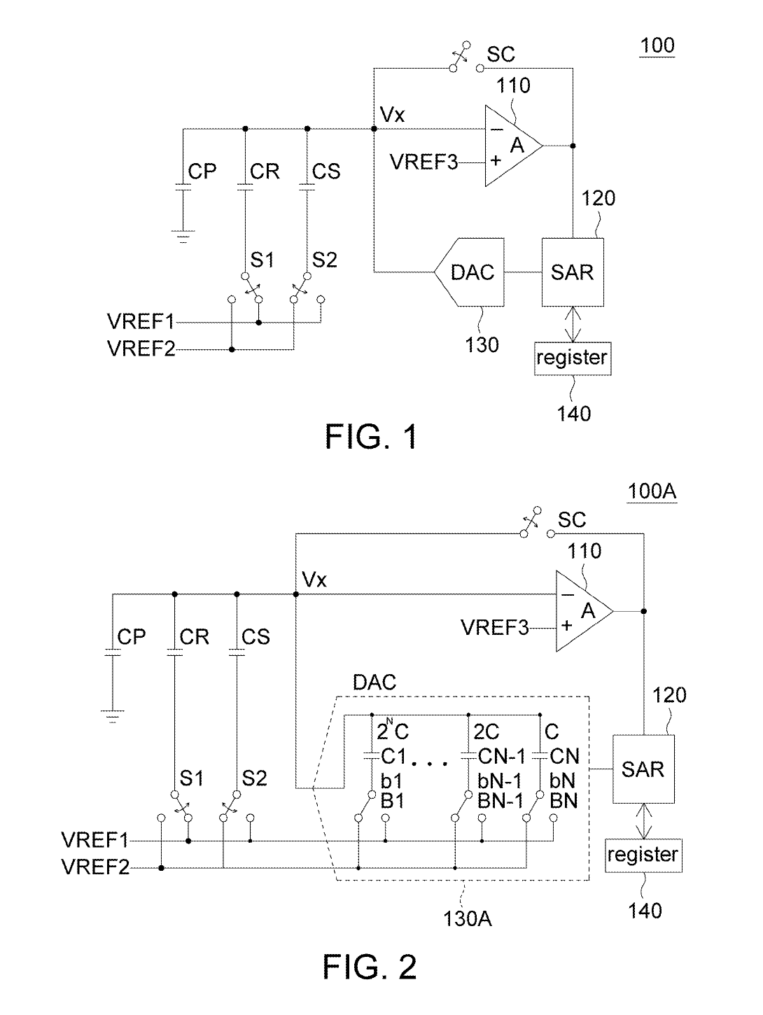

Referring to FIG. 1, which shows a capacitance measurement circuit of according to a first embodiment of the disclosure. As indicated in FIG. 1, the capacitance measurement circuit 100 includes a reference capacitor CR, a sensor capacitor CS, an operation amplifier 110, a successive approximation register (SAR) 120, a digital analog converter (DAC) 130, and switches S1, S2 and SC. Besides, CP denotes a parasitic capacitor of the capacitance measurement circuit 100. A register 140 is optional, which buffers a digital signal outputted from the SAR 120 or inputs a parameter to the SAR 120.

The reference capacitor CR is connected between the switch S1 and an inverse input terminal of the operation amplifier 110. The capacitance of the reference capacitor CR is known. The sensor capacitor CS is connected between the switch S2 and the inverse input terminal of the operation amplifier 110. The capacitance of the sensor capacitor CS is unknown, and varies with the user's operation (such as pressing). In other possible embodiments of the disclosure, the reference capacitor CR and the sensor capacitor CS can be both connected to a non-inverse input terminal of the operation amplifier 110.

The inverse input terminal of the operation amplifier 110 is connected to the reference capacitor CR and the sensor capacitor CS. The non-inverse input terminal of the operation amplifier 110 is connected to the reference voltage VREF3. An output terminal of the operation amplifier 110 is connected to the SAR 120. The SAR 120 receives an analog output voltage from the operation amplifier 110, and accordingly outputs a digital signal to the DAC 130. The DAC 130 receives the digital signal outputted from the SAR 120, and accordingly couples charges to the inverse input terminal of the operation amplifier 110.

One terminal of the switch S1 is connected to the reference capacitor CR, and the other terminal of the switch S1 is selectively connected to one of the reference voltages VREF1 and VREF2. Basically, the reference voltages VREF1 and VREF2 are different. One terminal of the switch S2 is connected to the sensor capacitor CS, and the other terminal of the switch S2 is selectively connected to one of the reference voltages VREF1 and VREF2. One terminal of the switch SC is connected to the inverse input terminal of the operation amplifier 110, and the other terminal of the switch SC is connected to the output terminal of the operation amplifier 110 (in other possible embodiments of the disclosure, the other terminal of the switch SC is connected to the reference voltage VREF3). The reference voltage VREF1 is such as an operation voltage. The reference voltage VREF2 is such as a ground voltage. For the convenience of design, the reference voltage VREF3 is such as the operating voltage or the ground voltage, but the present embodiment of the disclosure is not limited to the above exemplification.

The principles of the operation of the capacitance measurement circuit 100 of the present embodiment of the disclosure are disclosed below. Firstly, in an initial state, the switch S1 is connected to the reference voltage VREF2; the switch S2 is connected to the reference voltage VREF1; and the switch SC is connected to the third reference voltage VREF3 or the output terminal of the operation amplifier 110 so that the inverse input terminal of the operation amplifier is charged/discharged to the reference voltage VREF3. Meanwhile, the operation amplifier can be regarded as a unity gain amplifier whose input voltages and output voltage are basically equal. In the disclosure below, VX denotes a node as well as a node voltage thereof. The above operation is for initializing the operation amplifier. In greater details, the voltage at the inverse input terminal and the voltage at the non-inverse input terminal are initialized so that the two terminal voltages are equal. However, the present embodiment and other possible embodiments of the disclosure are not limited thereto. Besides, in the following embodiments and other possible embodiments of the disclosure, two input voltages of the operation amplifier equal through the initialization process.

Next, when measurement begins, the switch S1 is switched to the reference voltage VREF1 from the reference voltage VREF2, the switch S2 is switched to the reference voltage VREF2 from the reference voltage VREF1, and the switch SC is turned-off. Since the switch S1 is switched to the reference voltage VREF1 from the reference voltage VREF2, the reference capacitor CR couples a charge amount QR to the node VX through the coupling effect of the reference capacitor CR. The charge amount QR is expressed as formula (1):

QR=(VREF1−VREF2)*CR (1)

Likewise, since the switch S2 is switched to the reference voltage VREF2 from the reference voltage VREF1, the sensor capacitor CS couples a charge amount QS to the node VX through the coupling effect of the sensor capacitor CS. The charge amount QS is expressed as formula (2):

QS=(VREF2−VREF1)*CS (2)

If the sensor capacitor CS and the reference capacitor CR have different capacitances, then the node voltage VX is not equal to the reference voltage VREF3. The operation amplifier 110, used as a voltage comparer, compares the node voltages VX to the reference voltage VREF3, and further transmits a voltage difference to the SAR 120. According to an analog output voltage from the operation amplifier 110, the SAR 120 approximates the digital output signal, and further transmits the adjusted digital output signal to the DAC 130. After that, the DAC 130 directly couples a charge amount QC to the inverse input terminal of the operation amplifier 110 according to the digital output signal from the SAR 120; or the DAC 130 charges or discharges the node voltage VX. Particularly, if the capacitance of the reference capacitor CR is larger than the sensor capacitor CS and VREF1>VREF2, then VX>VREF3, and vice versa.

Through the successive approximation of the SAR 120, the node voltage VX is close to the reference voltage VREF3. Thus, the output digital signal from the SAR 120 reflects the capacitance difference between the sensor capacitor CS and the reference capacitor CR to calculate the capacitance of the sensor capacitor CS.

Furthermore, in other possible embodiments of the disclosure, the operation of the switches S1 and S2 can be changed as follows. In an initial state, the switch S1 is connected to the reference voltage VREF1, and the switch S2 is connected to the reference voltage VREF2. When the measurement begins, the switch S1 is switched to the reference voltage VREF2 from the reference voltage VREF1, and the switch S2 is switched to the reference voltage VREF1 from the reference voltage VREF2. That is, in the initial state, the switches S1 and S2 are connected to different voltages. When the measurement begins, the switches S1 and S2 are connected to different voltages. When measurement begins, the switches S1 and S2 are switched to different voltages so as to couple respective charge amounts to the node VX.

DAC 130 can have many implementations disclosed below.

FIG. 2 shows a capacitance measurement circuit 100A according to a second embodiment of the disclosure. As indicated in FIG. 2, the DAC 130A includes a plurality of capacitors C1˜CN and a plurality of switches B1˜BN. The capacitances of the capacitors C1˜CN respectively are 2^{N}C, . . . 2C, C and N is a positive integer. The switches B1˜BN are respectively controlled by the control signals b1˜bN, so that the capacitors C1˜CN are connected to the reference voltage VREF1 or the reference voltage VREF2.

The DAC 130A is such as a binary-array charge-redistribution DAC. From FIG. 2, the charge amount QC directly coupled to the operation amplifier by the DAC 130A is expressed as formula (3):

QC=VREF*(b1*2^{N}C+b2*2^{N-1}C+ . . . +bN*C) (3)

If bi=1 (i=1˜N), this implies that the switch is switched to the reference voltage VREF1 from the reference voltage VREF2; if bi=−1, this implies that the switch is switched to the reference voltage VREF2 from the reference voltage VREF1; and if bi=0, this implies that the switch is not switched. After successive approximation, the node voltage VX is close to 0; and the control signals bN˜b1 (outputted from SAR 120) reflect the capacitance difference between the sensor capacitor CS and the reference capacitor CR to calculate the capacitance of the sensor capacitor CS.

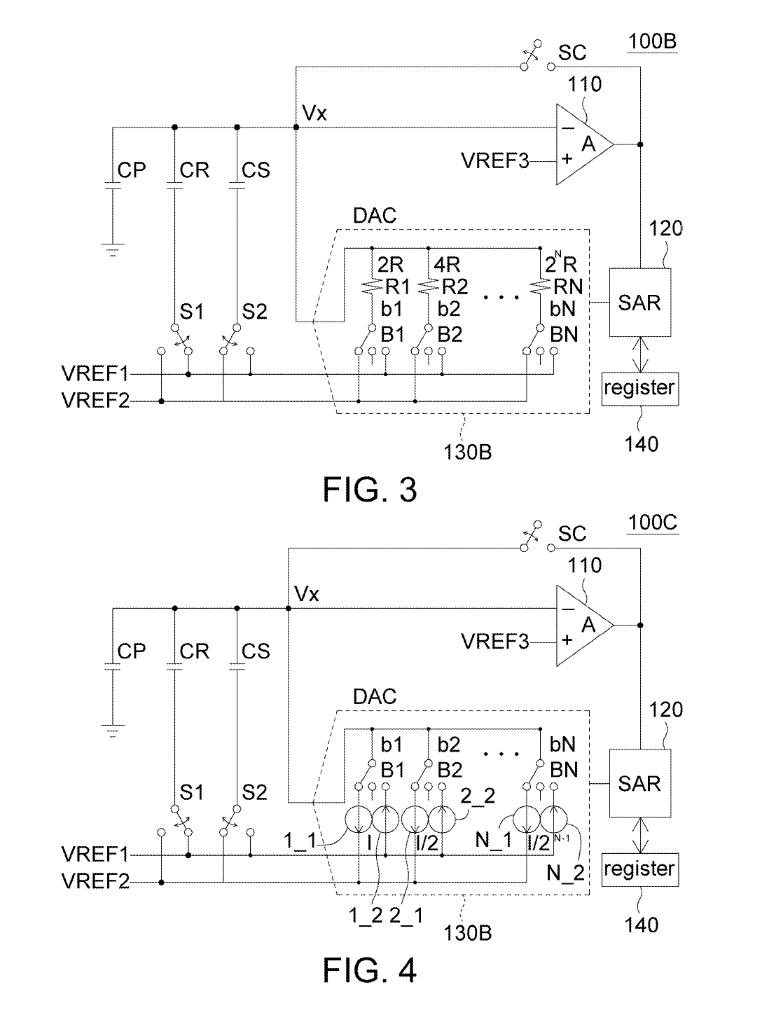

FIG. 3 shows a capacitance measurement circuit 100B according to a third embodiment of the disclosure. As indicated in FIG. 3, DAC 130B includes a plurality of resistors R1˜RN and a plurality of switches B1˜BN. The resistances of the resistors R1˜RN are respectively 2R, 4R . . . 2^{N}R and N is a positive integer. The switches B1˜BN are respectively controlled by the control signals b1˜bN, so that the resistors R1˜RN are connected to the reference voltage VREF1 or the reference voltage VREF2. Besides, in the third embodiment, the reference voltage VREF3 can be the average value of the reference voltages VREF1 and VREF2 (that is, the reference voltage VREF3=0.5*(VREF1+VREF2).

The DAC 130B is such as a binary weighted resistor DAC.

That is, the DAC 130B charges or discharges the node voltage VX, so that the node voltage VX approximates the reference voltage VREF3. Particularly, under VREF1>VREF2, if VX<VREF3 (that is, CR<CS), the DAC 130B charges the node voltage VX to be close to the reference voltage VREF3; and if VX>VREF3 (that is, CR>CS), the DAC 130B discharges the node voltage VX to be close to the reference voltage VREF3.

After successive approximation, the node voltage VX is close to the reference voltage VREF3; and the control signals bN˜b1 (outputted from SAR 120) reflect the capacitance difference between the sensor capacitor CS and the reference capacitor CR to calculate the capacitance of the sensor capacitor CS.

FIG. 4 shows a capacitance measurement circuit 100C according to a fourth embodiment of the disclosure. As indicated in FIG. 4, the DAC 130C includes a plurality of constant current pairs and a plurality of switches B1˜BN. The constant current pairs includes: the constant current sinks 1_1, 2_1, . . . N_1 which sink the currents I, I/2 . . . I/2^{N-1} and the constant current sources 1_2, 2_2, . . . N_2 which output the currents I, I/2 . . . I/2^{N-1} and N is a positive integer. The switches B1˜BN are respectively controlled by the control signals b1˜bN, so that the node VX is connected to the reference voltage VREF1 or the reference voltage VREF2 or floating. The node VX is discharged if the node VX is connected to the current sinks 1_1, 2_1, . . . N_1 via the switches. To the contrary, the node VX is charged if the node VX is connected to the current source 1_2, 2_2, . . . N_2 via the switches.

The DAC 130C is such as a binary current DAC. From FIG. 4, the charge amount QC directly coupled to the operation amplifier by the DAC 130C is expressed as formula (4):

QC=Δt*(b1*I+b2*(I/2)+ . . . +bN*(I/2^{N-1})} (4)

Δt denotes unit time. If bi=1, this implies that the switch is connected to the current source 1_2, 2_2, . . . N_2; If bi=−1, this implies that the switch is switched to the current sinks 1_1, 2_1, . . . N_1; If bi=0, this implies that the switch is floating.

That is, through the operation of charging or discharging the node voltage VX by the DAC 130C, the node voltage VX approximates the reference voltage VREF3. Particularly, under VREF1>VREF2, if VX<VREF3 (that is, CR<CS), the DAC 130C charges the node voltage VX to be close to the reference voltage VREF3; and to the contrary, if VX>VREF3 (that is, CR>CS), the DAC 130C discharges the node voltage VX to be close to the reference voltage VREF3.

After successive approximation, the node voltage VX is close to the reference voltage VREF3. The control signals bN˜b1 (outputted from the SAR 120) reflect the capacitance difference between the sensor capacitor CS and the reference capacitor CR to calculate the capacitance of the sensor capacitor CS.

The capacitance measurement circuit disclosed in the above respective embodiment of the disclosure has many advantages. For example, since the capacitance measurement circuit can measure without additional coupling capacitors, the circuit area is decreased and the circuit cost reduced.

It will be appreciated by those skilled in the art that changes could be made to the disclosed embodiments described above without departing from the broad inventive concept thereof. It is understood, therefore, that the disclosed embodiments are not limited to the particular examples disclosed, but is intended to cover modifications within the spirit and scope of the disclosed embodiments as defined by the claims that follow.

What is claimed is:

1. A capacitance measurement circuit, comprising:
a reference capacitor having a first terminal and a second terminal, the first terminal selectively connected to a first reference voltage or a second reference voltage;
a sensor capacitor having a first terminal and a second terminal, the first terminal selectively connected to the first reference voltage or the second reference voltage;
an operation amplifier having a first input terminal, a second input terminal and an output terminal, the first input terminal connected to the second terminal of the reference capacitor and the second terminal of the sensor capacitor, and the second input terminal connected to a third reference voltage;
an approximation unit having an input terminal and an output terminal, the input terminal connected to the output terminal of the operation amplifier; and
a conversion unit having an input terminal and an output terminal, the input terminal connected to the output terminal of the approximation unit, and the output terminal is directly connected to the first input terminal of the operation amplifier;
wherein the reference capacitor and the sensor capacitor respectively couple a first charge amount and a second charge amount to the first input terminal of the operational amplifier to conduct an input voltage at the first input terminal of the operational amplifier; and the conversion unit directly couples a third charge amount to the first input terminal of the operation amplifier or the conversion unit charges or discharges the first input terminal of the operation amplifier, until the input voltage at the first input terminal of the operation amplifier approximates the third reference voltage.

2. The capacitance measurement circuit according to claim 1, wherein
if the sensor capacitor and the reference capacitor have different capacitances, then the input voltage at the first input terminal of the operation amplifier is different from the third reference value, and the operation amplifier transmits an output voltage to the approximation unit;
the approximation unit outputs a digital output signal to the conversion unit according to the output voltage of the operation amplifier;
the conversion unit couples the third charge amount to the first input terminal of the operation amplifier according to the digital output signal from the approximation unit; or the conversion unit charges or discharges the input voltage at the first input terminal of the operation amplifier according to the digital output signal from the approximation unit; and
the approximation unit performs a successive approximation operation until the input voltage approximates the third reference voltage, and the digital output signal from the approximation unit reflects a capacitance difference between the sensor capacitor and the reference capacitor to calculate the capacitance of the sensor capacitor.

3. The capacitance measurement circuit according to claim 1, further comprising:
a first switch having a first terminal and a second terminal, the first terminal connected to the first terminal of the reference capacitor, the second terminal selectively connected to the first reference voltage or the second reference voltage;
a second switch having a first terminal and a second terminal, the first terminal connected to the first terminal of the sensor capacitor, and the second terminal selectively connected to the first reference voltage or the second reference voltage; and
a third switch having a first terminal and a second terminal, the first terminal connected to the first input terminal of the operation amplifier, and the second terminal selectively connected to the third reference voltage or the output terminal of the operation amplifier.

4. The capacitance measurement circuit according to claim 3, wherein in an initial state,
the first switch is connected to the second reference voltage;
the second switch is connected to the first reference voltage;
the third switch connects the first input terminal of the operation amplifier to the third reference voltage or to the output terminal of the operation amplifier.

5. The capacitance measurement circuit according to claim 4, wherein when measurement begins:
the first switch is switched to the first reference voltage from the second reference voltage to couple the first charge amount to the first input terminal of the operation amplifier;
the second switch is switched to the second reference voltage from the first reference voltage to couple the second charge amount to the first input terminal of the operation amplifier; and
the third switch is turned off.

6. A capacitance measurement method, comprising:
initializing an operation amplifier;
selectively switching a reference capacitor to a first reference voltage or a second reference voltage to couple a first charge amount to a first input terminal of the operation amplifier, wherein a second input terminal of the operation amplifier is connected to a third reference voltage;
selectively switching a sensor capacitor to the first reference voltage or the second reference voltage to couple a second charge amount to the first input terminal of the operation amplifier;
comparing an input voltage at the first input terminal of the operation amplifier with the third reference voltage; and
directly coupling a third charge amount to the first input terminal of the operation amplifier or charging/discharging the first input terminal of the operation amplifier according to the comparison result by successive approximation until the input voltage approximates the third reference voltage, wherein a successive approximation result reflects a capacitance of the sensor capacitor.

7. The capacitance measurement method according to claim 6, wherein
if the sensor capacitor and the reference capacitor have different capacitances, then the input voltage at the first input terminal of the operation amplifier is different from the third reference value, and the operation amplifier compares and transmits an output voltage;
outputting a digital output signal according to the output voltage from the operation amplifier;
coupling the third charge amount to the first input terminal of the operation amplifier or charging/discharging the first input terminal of the operation amplifier according to the digital output signal; and
performing a successive approximation operation until the input voltage approximates the third reference voltage, wherein the digital output signal reflects a capacitance difference between the sensor capacitor and the reference capacitor to calculate the capacitance of the sensor capacitor.

8. The capacitance measurement method according to claim 6, in an initial state, the method further comprises:
connecting the reference capacitor to the second reference voltage and connecting the sensor capacitor to the first reference voltage; and
connecting the first input terminal of the operation amplifier to the third reference voltage or an output terminal of the operation amplifier.

9. The capacitance measurement method according to claim 6, wherein when measurement begins, the method further comprises:
switching the reference capacitor to the first reference voltage to couple the first charge amount to the first input terminal of the operation amplifier;
switching the sensor capacitor to the second reference voltage to couple the second charge amount to the first input terminal of the operation amplifier; and
disconnecting the first input terminal of the operation amplifier from the third reference voltage or the output terminal of the operation amplifier.
